(19) United States
(12) Patent Application Publication
(10) Pub. No.: US 2011/0058334 A1
(43) Pub. Date: Mar. 10, 2011

(54) FAN APPARATUS, ELECTRONIC DEVICE, AND FAN-ATTACHED CASE

(75) Inventors: Shinji TAKEMOTO, Kyoto (JP); Hideyuki TAKEMOTO, Kyoto (JP); Harushige OSAWA, Kyoto (JP); Tatsuya TATARA, Kyoto (JP)

(73) Assignee: NIDEC CORPORATION, Kyoto (JP)

(21) Appl. No.: 12/878,186

(22) Filed: Sep. 9, 2010

(30) Foreign Application Priority Data
Sep. 10, 2009 (JP) 2009-208879

(51) Int. Cl. H05K 7/20; F24F 7/06

(52) U.S. Cl. 361/695; 454/249

(57) ABSTRACT

A fan apparatus includes an array of a plurality of axial fans arranged in at least two rows and at least two columns in parallel with a mounting surface provided in a case of an electronic device. Each of the plurality of axial fans has a rotation axis extending perpendicularly or substantially perpendicularly to the mounting surface. At least one of the plurality of axial fans is arranged to rotate in a first rotation direction to introduce air into the case or discharge air out of the case, while the other of the plurality of axial fans are arranged to rotate in a second rotation direction opposite to the first rotation direction to cause a flow of air in the same direction in which the at least one axial fan is arranged to cause a flow of air. Thus, a reduction in noise is achieved.

### BACKGROUND OF THE INVENTION

1. Field of the Invention

The present invention relates to a fan apparatus to be attached to a case for an electronic device.

2. Description of the Related Art

A variety of fan apparatuses including a plurality of fans have been provided to be attached to cases designed to contain electronic devices. A heating element cooling apparatus 5 disclosed in FIG. 4 of JP-A 2002-368470, for example, includes a heat sink 2 having a plurality of straight fins 1, and two axial fans 4 placed on one side of the straight fins 1. In the heating element cooling apparatus 5, the two fans 4, placed side by side, are arranged to rotate in mutually opposite directions so that whirl flows of air between the two fans 4 may not cancel each other out but combine to cause a strong flow of air. This results in an increased heat transfer coefficient, leading to a reduced temperature of a heating element 3 placed in the vicinity of the heat sink 2.

JP-A 2008-140406 discloses another example of a conventional rack-mounted system 10 including fan/LAN tray slots 23. As shown in FIG. 8 of JP-A 2008-251067, each fan/LAN tray slot 23 is provided with eight air blowers. JP-A 2008-251067 discloses a power supply module 40 used for a disk array apparatus. In a fan portion 42 of the power supply module 40, two fans 43 having the same structure are arranged in tandem, one in front of the other, along an axial direction.

### SUMMARY OF THE INVENTION

With improved performance and increased density of electronic devices, cases for such electronic devices are required to have improved ventilation efficiency. Preferred embodiments of the present invention improve efficiency in introducing, sending, or discharging air into, inside, or out of such cases.

A fan apparatus according to a preferred embodiment of the present invention includes an array of a plurality of axial fans arranged in at least two rows and at least two columns in parallel or substantially in parallel with a mounting surface provided in a case of an electronic device. Each of the plurality of axial fans has a rotation axis extending perpendicularly or substantially perpendicularly to the mounting surface. At least one of the plurality of axial fans is arranged to rotate in a first rotation direction to introduce air into the case or discharge air out of the case, while the other of the plurality of axial fans are arranged to rotate in a second rotation direction opposite to the first rotation direction to cause a flow of air in the same direction in which the at least one axial fan is arranged to cause a flow of air.

Preferred embodiments of the present invention make it possible to introduce, send, or discharge air into, inside, or out of a case of an electronic device while achieving a reduction in noise.

Fan apparatuses according to preferred embodiments of the present invention can be used as fan apparatuses attached to a variety of electronic devices.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a rear view of an electronic device according to a first preferred embodiment of the present invention.

FIG. 2 is a plan view of the electronic device.

FIG. 3 is a rear view of an electronic device according to a second preferred embodiment of the present invention.

FIG. 4 is a plan view of the electronic device according to the second preferred embodiment of the present invention.

FIG. 5 is a plan view of an electronic device according to a third preferred embodiment of the present invention.

FIG. 6 is a right side view of the electronic device according to the third preferred embodiment of the present invention.

FIG. 7 is a left side view of the electronic device according to the third preferred embodiment of the present invention.

FIG. 8 is a plan view of an electronic device according to a fourth preferred embodiment of the present invention.

FIG. 9 is a right side view of the electronic device according to the fourth preferred embodiment of the present invention.

FIG. 10 is a front view of a rack-type electronic system according to a fifth preferred embodiment of the present invention.

FIG. 11 is a right side view of the rack-type electronic system.

FIG. 12 is a plan view of a fan apparatus according to the fifth preferred embodiment of the present invention.

FIG. 13 is a plan view of a fan apparatus according to another preferred embodiment of the present invention.

FIG. 14 is a plan view of a fan apparatus according to still another preferred embodiment of the present invention.

FIG. 15 is a plan view of a fan apparatus according to still another preferred embodiment of the present invention.

FIG. 16 is a right side view of a rack-type electronic system according to a sixth preferred embodiment of the present invention.

FIG. 17 is a plan view of a second fan apparatus according to the sixth preferred embodiment of the present invention.

FIG. 18 is a right side view of a rack-type electronic system according to a seventh preferred embodiment of the present invention.

FIG. 19 is a partial cross-sectional view of a contra-rotating fan according to the seventh preferred embodiment of the present invention.

### DETAILED DESCRIPTION OF THE PREFERRED EMBODIMENTS

### First Preferred Embodiment

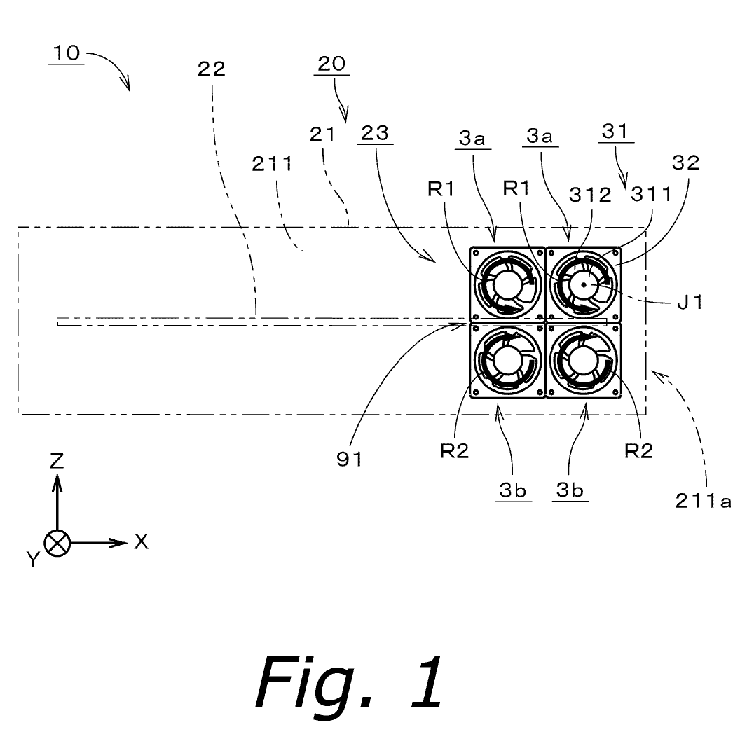

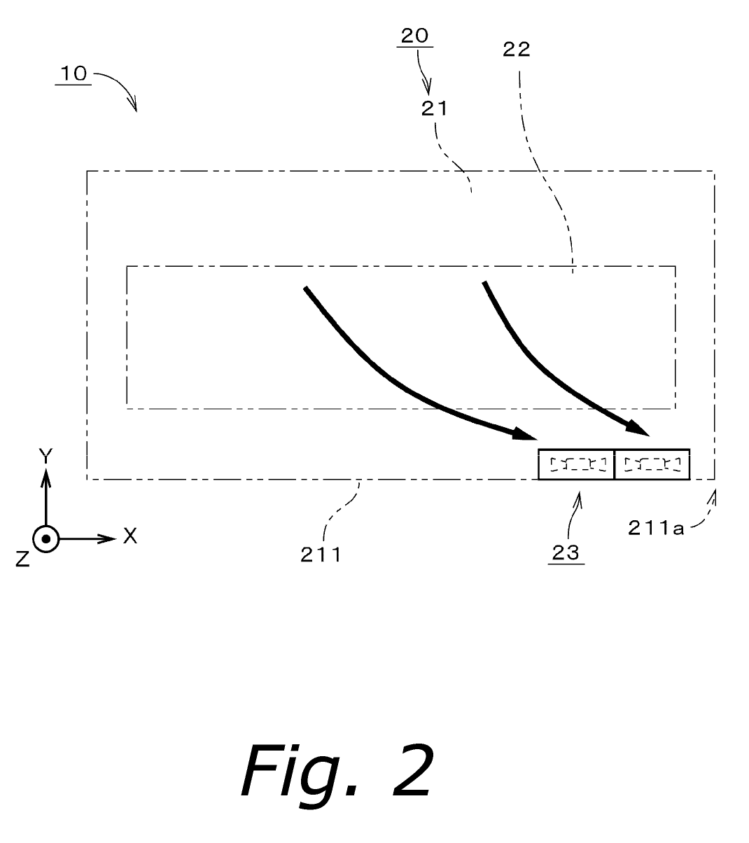

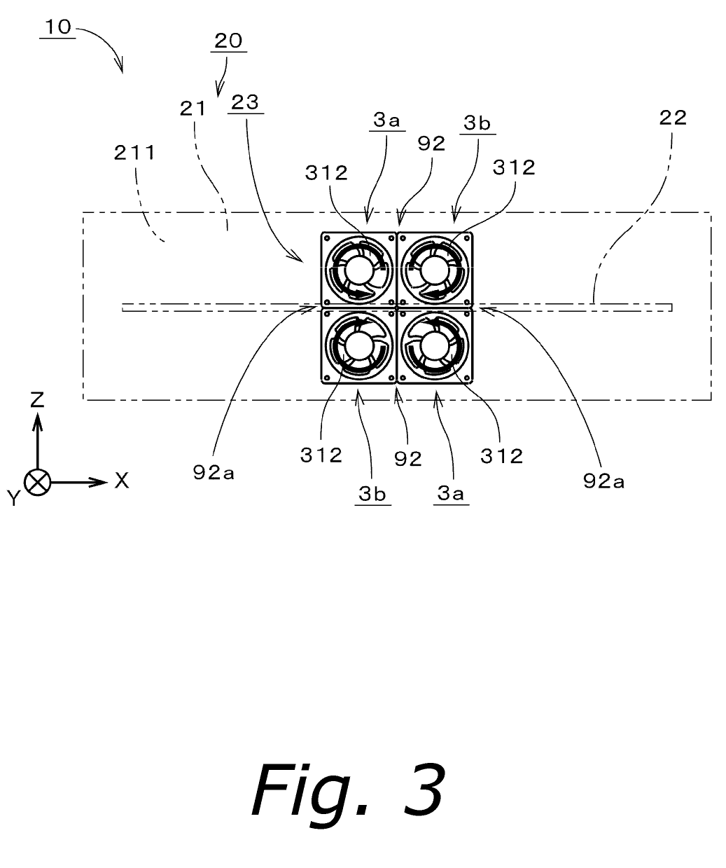

FIG. 1 is a rear view of an electronic device 10 according to a first preferred embodiment of the present invention. FIG. 2 is a plan view of the electronic device 10. A lower side of FIG. 2 corresponds to a rear of the electronic device 10, while an upper side of FIG. 2 corresponds to a front of the electronic device 10. The electronic device 10 is used, for example, as a digital versatile disc (DVD) drive apparatus, a desktop PC, or the like. The electronic device preferably 10 includes a fan-attached case 20 and a circuit board 22. In FIGS. 1 and 2, the circuit board 22 and a case 21 of the fan-attached case 20 are represented by chain double-dashed lines. The same is true of FIGS. 3, 4, 5, 6, 7, 8, and 9 described below.

The exterior of the case 20 in this preferred embodiment is that of a rectangular parallelepiped, but any other desired shaped could be used. A rear surface of the case defines a mounting surface to which a fan apparatus 23 is attached. The rear surface will be hereinafter referred to as a “mounting surface 211”. The fan apparatus 23 for the fan-attached case 20 is arranged to discharge air out of the case 21. On the mounting surface 211, the fan apparatus 23 is arranged one-sidedly near a side 211a of the case 21 defining a corner boundary between the mounting surface 211 and a right side surface of the case 21 as shown in FIG. 2. The circuit board 22 is arranged inside the case 21. A principal surface of the circuit board 22 is arranged perpendicularly to the side 211a. Hereinafter, a vertical direction of the electronic device 10 will be referred to as a “Z direction”, and a front-to-rear direction of the electronic device 10, which is perpendicular to the Z direction, will be referred to as a “Y direction”. A left-to-right direction of the electronic device 10, which is perpendicular or substantially perpendicular to both the Y and Z directions, will be hereinafter referred to as an “X direction”. Note that upper and lower sides along the Z direction may not necessarily coincide with upper and lower sides, respectively, along the direction of gravity. The same is true of the other figures.

As illustrated in FIG. 1, the fan apparatus 23 includes two first axial fans 3a and two second axial fans 3b. The first axial fans 3a are arranged side by side in a row in a longitudinal direction of the mounting surface 211 as shown in FIG. 1, i.e., in the X direction. The second axial fans 3b are arranged side by side in a row below the row of the first axial fans 3a in parallel or substantially in parallel with the mounting surface 211 and the row of the first axial fans 3a. As described above, the first and second axial fans 3a and 3b are arranged in an array of two rows and two columns in parallel or substantially in parallel with the mounting surface 211.

Each of the first axial fans 3a is arranged to rotate counterclockwise as indicated by arrow R1 in FIG. 1. Each of the second axial fans 3b is arranged to rotate clockwise as indicated by arrow R2 to cause a flow of air in the same direction in which the first axial fans 3a are arranged to cause a flow of air. Note that the expressions “first axial fan 3a” and “second axial fan 3b” are used simply for the sake of convenience to distinguish differences in rotation direction. The same holds true in descriptions of other preferred embodiments provided below. A rotation axis J1 of each of the first and second axial fans 3a and 3b is arranged to extend in the Y direction, which is perpendicular to the mounting surface 211. In FIG. 1, the reference symbol “J1” is assigned to the rotation axis of only one of the first axial fans 3a. In the fan apparatus 23, a boundary 91 between the upper row of the two first axial fans 3a and the lower row of the two second axial fans 3b is perpendicular or substantially perpendicular to the side 211a. Hereinafter, unless the first axial fans 3a and the second axial fans 3b need to be differentiated from each other, the first and second axial fans 3a and 3b will be referred to as “axial fans 3”. The same holds true in the descriptions of the other preferred embodiments provided below.

Each of the axial fans 3 includes a motor, an impeller 31, and a housing 32. The motor is a direct current brushless motor. The impeller 31 includes a central cup portion 311 and a plurality of blades 312. The blades 312 are arranged to project radially outward from an outside surface of the cup portion 311. The motor is placed inside the cup portion 311. The housing 32 is arranged to surround an outer circumference of the impeller 31.

Near the boundary 91, top portions of the blades 312 in each axial fan 3 are arranged to move in the direction of the side 211a to cause a flow of air traveling in a positive X direction along the boundary 91. As illustrated in FIG. 2, on an imaginary plane in the middle in the Z direction of the case 21, flows of air traveling inside the case 21 toward the fan apparatus 23 are steeply slanted in a negative X direction when viewed from the fan apparatus 23, which allows a sufficient amount of air in a wide range to be discharged out of the case 21. This results in efficient cooling of the circuit board 22 placed in a center of the case 21. As illustrated in FIG. 1, the circuit board 22 is arranged perpendicularly to the side 211a and along the boundary 91 to permit the air to be discharged out of the case 21 without the circuit board 22 blocking the passage of the air.

The first preferred embodiment has been described above. Referring to FIG. 1, the top portions of the blades 312 of all the axial fans 3 in the fan apparatus 23 are arranged to move in the same direction near the boundary 91, so that whirl components of flows of air caused by the respective axial fans 3 are oriented in the same direction. This leads to an efficient discharge of air while achieving a reduction in noise, i.e., so-called wind noise, caused by the flows of air being discharged through the fan apparatus 23.

In a modification of the electronic device 10, the fan apparatus 23 may be arranged to introduce air into the case 21. In the fan apparatus 23 according to this modification, the lower row of the axial fans are arranged to rotate counterclockwise when viewed from the rear to introduce air into the case 21, while the upper row of the axial fans are arranged to rotate clockwise to introduce air into the case 21. The top portions of the blades 312 of all the axial fans 3 are thus arranged to move away from the side 211a near the boundary 91 illustrated in FIG. 1, to achieve an efficient introduction of air into the case 21 while achieving a reduction in the noise caused by the flows of air. The flows of air introduced through the fan apparatus 23 into the case 21 illustrated in FIG. 2 are steeply slanted in the negative X direction when viewed from the fan apparatus 23, on an imaginary plane in the middle in the Z direction of the case 21, so as to spread widely inside the case 21. The air is introduced into the case 21 without the circuit board 22 blocking the passage of the air, because the circuit board 22 is arranged along the boundary 91.

### Second Preferred Embodiment

FIG. 3 is a rear view of an electronic device 10 according to a second preferred embodiment of the present invention. In a fan-attached case 20 of the electronic device 10, a fan apparatus 23 is arranged substantially in a center in the X direction of a rear surface, i.e., a mounting surface 211, of a case 21. The fan apparatus 23 includes four axial fans 3a and 3b arranged in an array of two rows and two columns. Specifically, two first axial fans 3a arranged to rotate counterclockwise when viewed from the rear are arranged in upper left-hand and lower right-hand corners in FIG. 3, while two second axial fans 3b arranged to rotate clockwise are arranged in upper right-hand and lower left-hand corners. That is, each axial fan 3 is arranged to rotate in an opposite direction to that in which the adjacent one of the axial fans 3 in each of row and column directions of the array, i.e., the X and Z directions, is arranged to rotate. In the other respects, the electronic device 10 according to the second preferred embodiment is similar in structure to the electronic device 10 illustrated in FIG. 1. In the following description, components that have their counterparts in the electronic device 10 illustrated in FIG. 1 are assigned the same reference numerals as those of the counterparts.

In the fan apparatus 23, top portions of blades 312 of each pair of adjacent axial fans 3 in either the X direction or the Z direction are arranged to move in the same direction near a boundary 92 between the pair. There are four such boundaries 92. This arrangement contributes to reducing the noise caused by the flows of air. In FIG. 3, reference symbol “92a” is assigned to two of the four boundaries 92 which are oriented parallel to a longitudinal direction of the mounting surface 211.

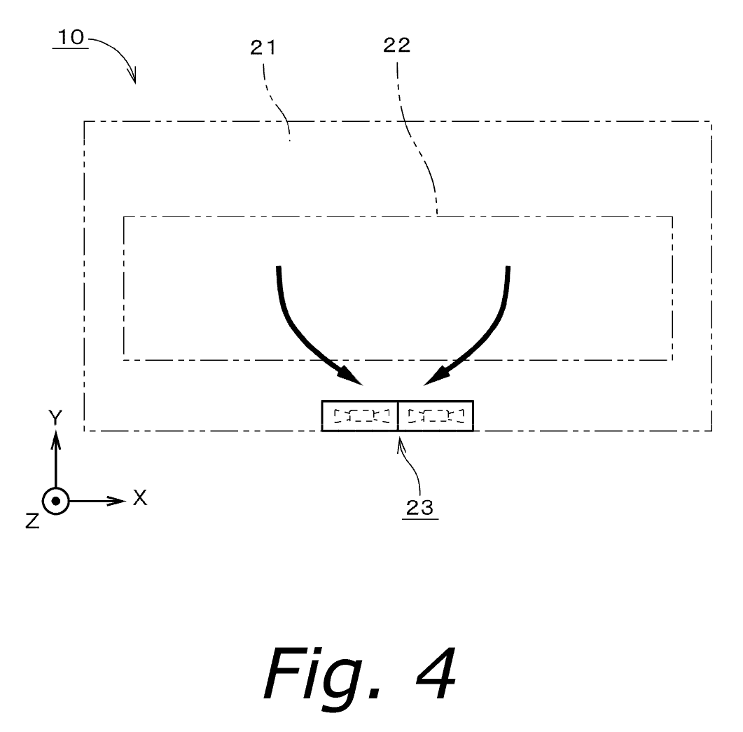

Near each of the boundaries 92a, the top portions of the blades 312 of both the adjacent axial fans 3 each on one side of the boundary 92a are arranged to move in the direction of a center of the fan apparatus 23, i.e., a center of the array of the axial fans 3, to cause flows of air traveling along the boundaries 92a from the left toward the center and from the right toward the center in the figure. As a result, as illustrated in FIG. 4, which is a plan view of the electronic device 10, air inside the case 21 flows toward the fan apparatus 23 with flows of air steeply slanted to both sides along the X direction on an imaginary plane in the middle in the Z direction of the case 21, which allows a sufficient amount of air in a wide range to be efficiently discharged out of the case 21. In addition, a circuit board 22 placed in the center inside the case 21 is efficiently cooled. The air is discharged out of the case 21 without the circuit board 22 blocking the passage of the air, because the circuit board 22 is arranged along the boundaries 92a as illustrated in FIG. 3.

In a modification of the second preferred embodiment, the fan apparatus 23 may be arranged to introduce air into the case 21. In the fan apparatus 23 according to this modification, each axial fan is arranged to rotate in an opposite direction to cause a flow of air in an opposite direction, as compared to its counterpart in the second preferred embodiment. Near the boundaries 92a, the top portions of the blades 312 of all the axial fans are arranged to move away from the center of the fan apparatus 23. The air introduced through the fan apparatus 23 into the case 21 illustrated in FIG. 4 will spread inside the case 21 efficiently and widely from the fan apparatus 23 to both sides along the X direction, on the imaginary plane in the middle in the Z direction of the case 21.

### Third Preferred Embodiment

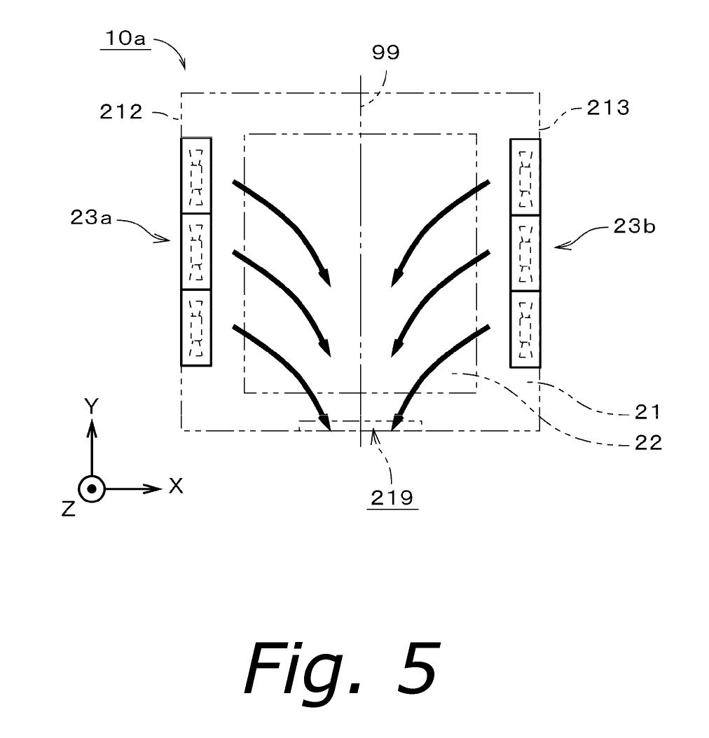

FIG. 5 is a plan view of an electronic device 10a according to a third preferred embodiment of the present invention. An upper side of FIG. 5 corresponds to a front of the electronic device 10a, while a lower side of FIG. 5 corresponds to a rear of the electronic device 10a. In the electronic device 10a, a first fan apparatus 23a and a second fan apparatus 23b are attached to a right side surface of a case 21, which is shown on the left-hand portion of FIG. 5, and a left side surface of the case 21, which is shown on the right-hand portion of FIG. 5, respectively. In the electronic device 10a, the first and second fan apparatuses 23a and 23b are arranged to introduce air into the case 21. Hereinafter, the right side surface and the left side surface of the case 21 will be referred to as a “first mounting surface 212” and a “second mounting surface 213”, respectively. In the other respects, the electronic device 10a is substantially similar in structure to the electronic device illustrated in FIG. 1. In the following description, components that have their counterparts in the electronic device illustrated in FIG. 1 are assigned the same reference numerals as those of the counterparts.

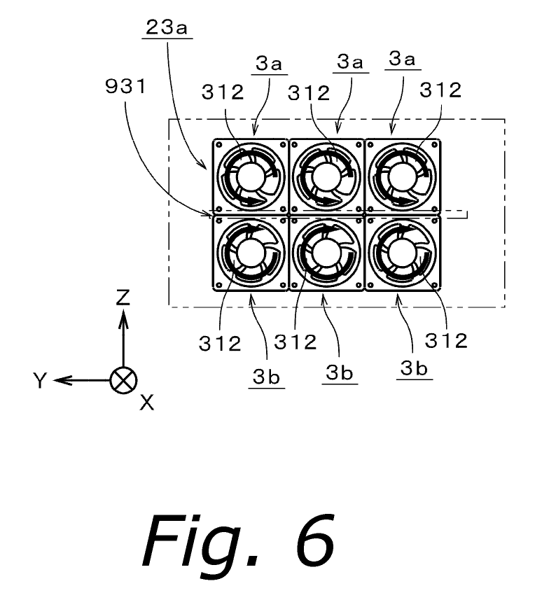

FIG. 6 is a diagram illustrating the first fan apparatus 23a. In the first fan apparatus 23a, three first axial fans 3a are arranged in a row in the Y direction, while, below the row of the first axial fans 3a, three second axial fans 3b are arranged in a row in the Y direction. Each of the first axial fans 3a is arranged to rotate counterclockwise when viewed from outside the case 21, while each of the second axial fans 3b is arranged to rotate clockwise.

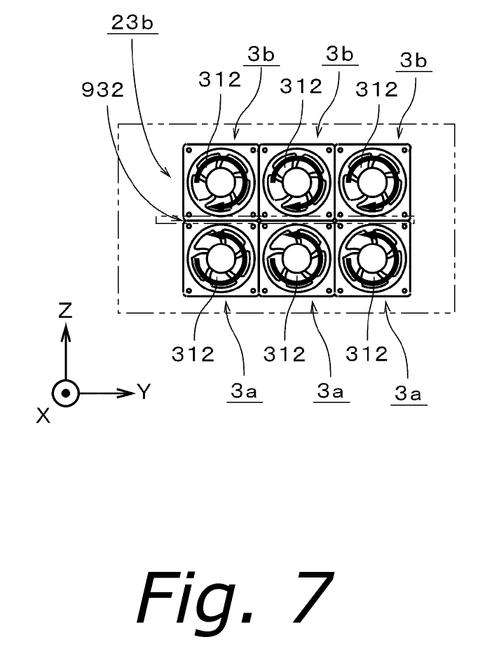

FIG. 7 is a diagram illustrating the second fan apparatus 23b. In the second fan apparatus 23b, three second axial fans 3b are arranged in a row in the Y direction, while, below the row of the second axial fans 3b, three first axial fans 3a are arranged in a row in the Y direction. Also in the second fan apparatus 23b, each of the first axial fans 3a is arranged to rotate counterclockwise when viewed from outside the case 21, while each of the second axial fans 3b is arranged to rotate clockwise. That is, in the electronic device 10a illustrated in FIG. 5, the first and second fan apparatuses 23a and 23b are symmetric with respect to an imaginary plane 99 parallel or substantially parallel to both the first mounting surface 212 and the opposing second mounting surface 213 and positioned in the middle between the first and second mounting surfaces 212 and 213.

In the first fan apparatus 23a illustrated in FIG. 6, near a boundary 931 between the row of the first axial fans 3a and the row of the second axial fans 3b, top portions of blades 312 of all the first and second axial fans 3a and 3b are arranged to move in a negative Y direction, i.e., in the direction of the rear of the electronic device 10a, to cause a flow of air traveling along the boundary 931 in the negative Y direction. Flows of air introduced into the case 21 through the first fan apparatus 23a illustrated in FIG. 5 are thus steeply slanted in the negative Y direction while traveling in the positive X direction, on an imaginary plane in the middle in the Z direction of the case 21.

Similarly, in the second fan apparatus 23b illustrated in FIG. 7, near a boundary 932 between the row of the first axial fans 3a and the row of the second axial fans 3b, top portions of blades 312 of all the first and second axial fans 3a and 3b are arranged to move in the negative Y direction to cause a flow of air traveling along the boundary 932 in the negative Y direction. As illustrated in FIG. 5, flows of air introduced into the case 21 through the second fan apparatus 23b are thus steeply slanted in the negative Y direction while traveling in the negative X direction, on an imaginary plane in the middle in the Z direction of the case 21.

The flows of air caused by the first and second fan apparatuses 23a and 23b, respectively, pass through a central area inside the case 21, and are then discharged out of the case 21 through an air outlet 219 defined in a rear surface of the case 21. A large amount of air thus flows in the central area inside the case 21 to efficiently cool a circuit board 22 placed in the middle in the Z direction of the case 21.

In the third preferred embodiment, the top portions of the blades 312 of all the axial fans 3 in the first fan apparatus 23a are arranged to move in the same direction near the boundary 931 to achieve a reduction in the noise caused by the flows of air, while at the same time the top portions of the blades 312 of all the axial fans 3 in the second fan apparatus 23b are arranged to move in the same direction near the boundary 932 to achieve a reduction in the noise.

In a modification of the electronic device 10a, each of the first and second fan apparatuses 23a and 23b may be arranged to discharge air out of the case 21. In each of the first and second fan apparatuses 23a and 23b according to this modification, each axial fan is arranged to rotate in an opposite direction to cause a flow of air in an opposite direction, as compared to its counterpart in the third preferred embodiment. Flows of air traveling inside the case 21 illustrated in FIG. 5 toward the first fan apparatus 23a are steeply slanted in a positive Y direction while traveling in the negative X direction. On the other hand, flows of air traveling inside the case 21 toward the second fan apparatus 23b are steeply slanted in the positive Y direction while traveling in the positive X direction. This allows air in a wide range inside the case 21 to be efficiently discharged out of the case 21.

### Fourth Preferred Embodiment

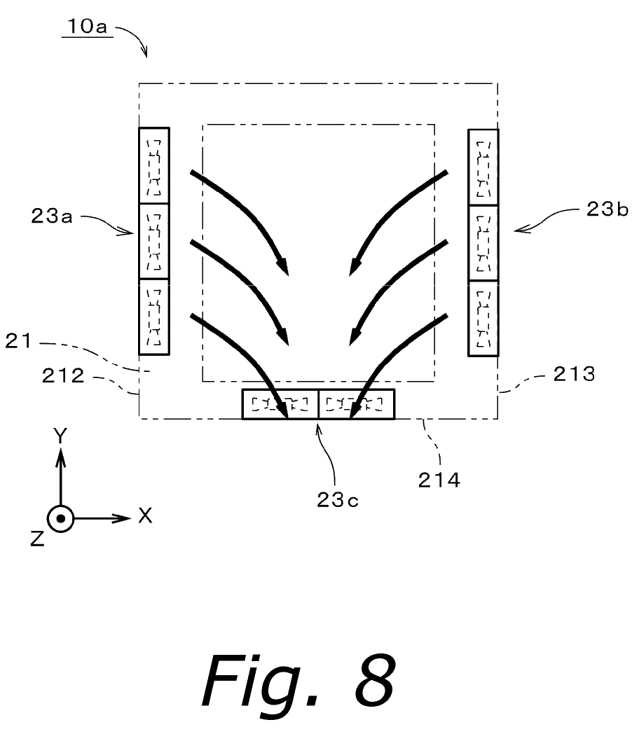

FIG. 8 is a plan view of an electronic device 10a according to a fourth preferred embodiment of the present invention. The electronic device 10a according to the fourth preferred embodiment is different from the electronic device illustrated in FIG. 5 in that an additional fan apparatus 23c is attached to the rear surface of the case 21 extending between the first and second mounting surfaces 212 and 213. The fan apparatus 23c is similar in structure to the fan apparatus 23 illustrated in FIG. 3. In the other respects, the electronic device 10a according to the fourth preferred embodiment is similar in structure to the electronic device 10a illustrated in FIG. 5. Hereinafter, the fan apparatus 23c will be referred to as a “third fan apparatus 23c”, and the rear surface of the case 21 will be referred to as a “third mounting surface 214”. In the electronic device 10a, the first and second fan apparatuses 23a and 23b are arranged to introduce air into the case 21, while the third fan apparatus 23c is arranged to discharge the air out of the case 21.

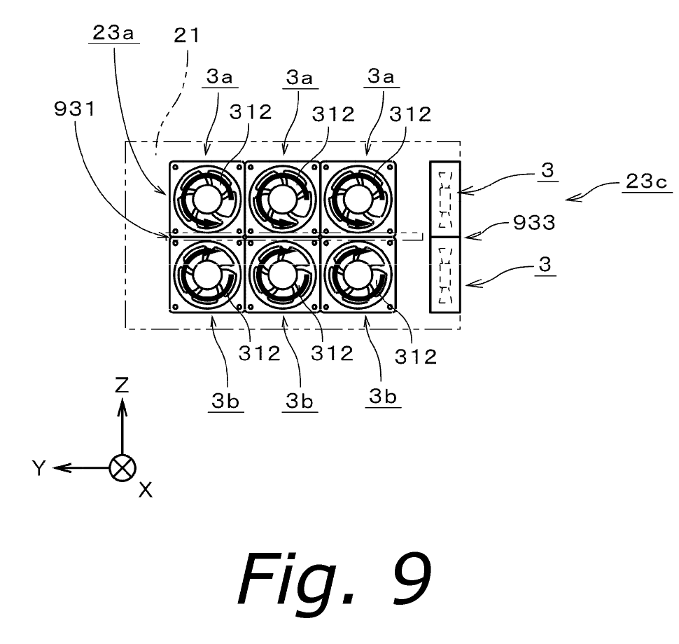

FIG. 9 is a diagram illustrating a left side of FIG. 8. The boundary 931 between the upper row of the first axial fans 3a and the lower row of the second axial fans 3b in the first fan apparatus 23a is at the same level in the Z direction as a boundary 933 between the upper row of the axial fans 3 and the lower row of the axial fans 3 in the third fan apparatus 23c. Similarly, the boundary 932 between the upper row of the second axial fans 3b and the lower row of the first axial fans 3a in the second fan apparatus 23b as illustrated in FIG. 7 is at the same level in the Z direction as the boundary 933 in the third fan apparatus 23c illustrated in FIG. 9. Thus, the air introduced into the case 21 through each of the first and second fan apparatuses 23a and 23b and traveling toward the third mounting surface 214 will efficiently flow into the third fan apparatus 23c to be discharged out of the case 21. Like the fan apparatus 23 illustrated in FIG. 4, the third fan apparatus 23c is arranged to discharge air from a wide range inside the case 21, resulting in a further improvement in the efficiency in the air discharge.

In each of the first and second fan apparatuses 23a and 23b according to the fourth preferred embodiment, the top portions of the blades 312 of all the axial fans 3 are arranged to move in the direction of the third fan apparatus 23c near the boundary 931 or 932. This contributes to a reduction in the noise caused by the flows of air.

In a modification of the electronic device 10a according to the fourth preferred embodiment, in each of the first, second, and third fan apparatuses 23a, 23b, and 23c, each axial fan may be arranged to rotate in an opposite direction to cause a flow of air in an opposite direction, as compared to its counterpart in the fourth preferred embodiment. In such a modification, the top portions of the blades 312 of all the axial fans 3 in each of the first and second fan apparatuses 23a and 23b are arranged to move in the direction away from the third fan apparatus 23c near the boundary 931 or 932. This allows air introduced into the case 21 through the third fan apparatus 23c to be efficiently directed toward the first and second fan apparatuses 23a and 23b to be discharged out of the case 21 therethrough.

In each of the first, third, and fourth preferred embodiments described above, the top portions of the blades 312 of the paired axial fans are arranged to move in the same direction near the boundary therebetween to cause a flow of air along the boundary. This flow of air is employed to efficiently cool the inside of the case 21. The circuit board to be cooled is preferably arranged along the boundary between the paired axial fans inside the case 21. In this case, the flows of air caused by the axial fans will pass in the vicinity of the circuit board, leading to improved efficiency in cooling the circuit board.

### Fifth Preferred Embodiment

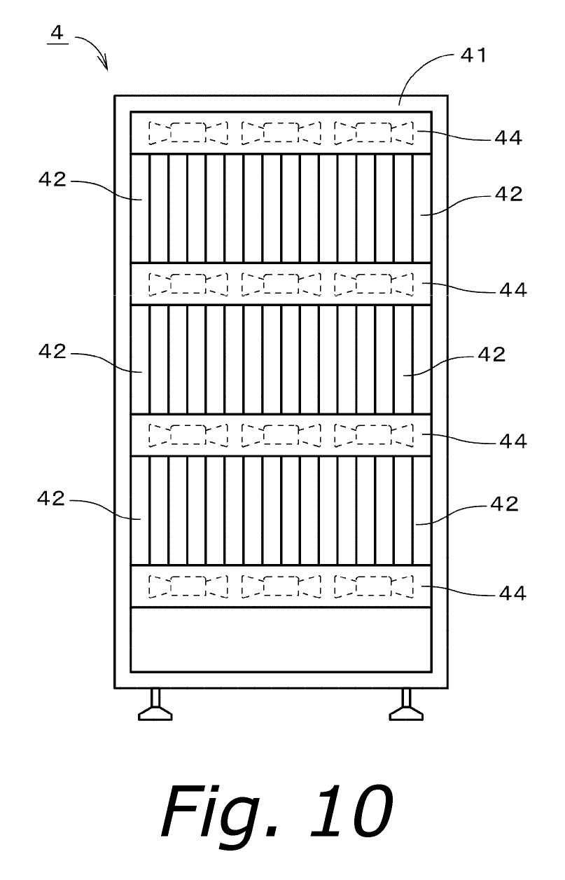

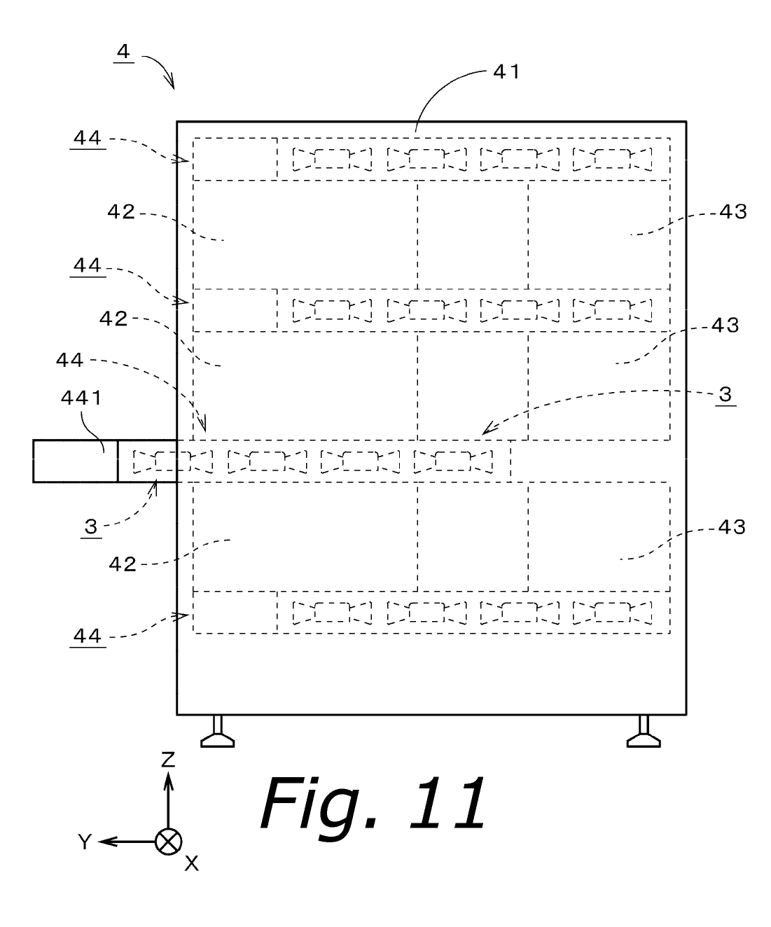

FIG. 10 is a front view of a rack-type electronic system 4 according to a fifth preferred embodiment of the present invention. FIG. 11 is a right side view of the rack-type electronic system 4. The rack-type electronic system 4, which is an electronic device, preferably includes a case 41, a plurality of substantially plate-shaped blade servers 42, a plurality of power supply units 43, and four fan apparatuses 44. Hereinafter, the blade servers 42 will be referred to simply as the “servers 42”.

The exterior of the case 41 is preferably in the shape of a rectangular parallelepiped, but any other desirable shape could be used. The case 41 contains the servers 42, the power supply units 43, and the fan apparatuses 44. The case 41 has openings on top and bottom portions thereof. The servers 42 are arranged horizontally and in an upright orientation. Three arrays of the servers 42 are provided at different vertical levels. As illustrated in FIG. 11, the power supply units 43 are arranged behind the arrays of the servers 42. Other components, such as a control device, a communication device, and the like, are arranged near the power supply units 43 as appropriate. The four fan apparatuses 44 are arranged above and below the arrays of the servers 42.

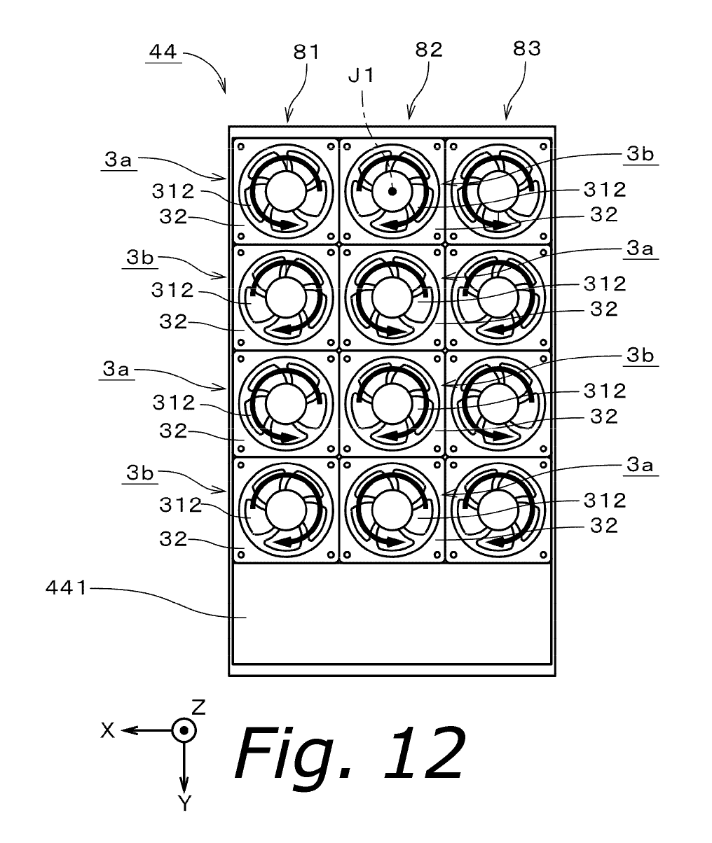

FIG. 12 is a plan view of the fan apparatus 44. A lower side of FIG. 12 corresponds to a front of the case 41, while an upper side of FIG. 12 corresponds to a rear of the case 41. The fan apparatus 44 is a so-called fan tray, and includes a plurality of axial fans 3 and a frame 441. In FIG. 12, the axial fans 3 are denoted by reference symbols “3a” and “3b”. The housings 32 of the axial fans 3 are joined together. In the case where the frame 441 is regarded as a horizontal mounting surface for the axial fans 3 provided in the case 41, the axial fans 3 are arranged in three columns parallel to the Y direction, with the rotation axis J1 of each axial fan 3 extending perpendicularly to the mounting surface. Each column includes a row of four of the axial fans 3. Hereinafter, the three columns parallel to the Y direction in the array of the axial fans 3 in the fan apparatus 44 will be referred to as a “first column 81”, a “second column 82”, and a “third column 83”, respectively, from left to right.

As illustrated in FIG. 11, the frame 441 is arranged to be capable of being horizontally inserted into and removed from the case 41 through the front of the case 41. This enables easy removal of the axial fans 3 from the case 41 to repair any of the axial fans 3 or replace any of the axial fans 3 with another axial fan 3. Note that FIG. 11 illustrates a situation in which the second fan apparatus 44 from the bottom has been drawn slightly out of the case 41. The same is true of other similar figures described below.

As illustrated in FIG. 12, in the first column 81 of the fan apparatus 44, two first axial fans 3a, each of which is arranged to rotate counterclockwise in a plan view, and two second axial fans 3b, each of which is arranged to rotate clockwise in the plan view, are arranged alternately, with one of the first axial fans 3a at the top. The same is true of the third column 83. In the second column 82, two second axial fans 3b and two first axial fans 3a are arranged alternately, with one of the second axial fans 3b at the top. That is, in the fan apparatus 44, each axial fan 3 is arranged to rotate in an opposite direction to that in which an adjacent one or ones of the axial fans 3 in each of the X and Y directions, i.e., row and column directions of the array, respectively, are arranged to rotate. Also in descriptions of other fan apparatuses of a fan tray type provided below, for the sake of convenience in explanation, those axial fans 3 which are arranged to rotate counterclockwise in a plan view will be referred to as “first axial fans 3a”, while those axial fans 3 which are arranged to rotate clockwise in the plan view will be referred to as “second axial fans 3b”.

In the fifth preferred embodiment, top portions of blades 312 of each pair of adjacent first and second axial fans 3a and 3b are arranged to move in the same direction near a boundary between the pair. This contributes to reducing noise caused by flows of air produced in the fan apparatus 44.

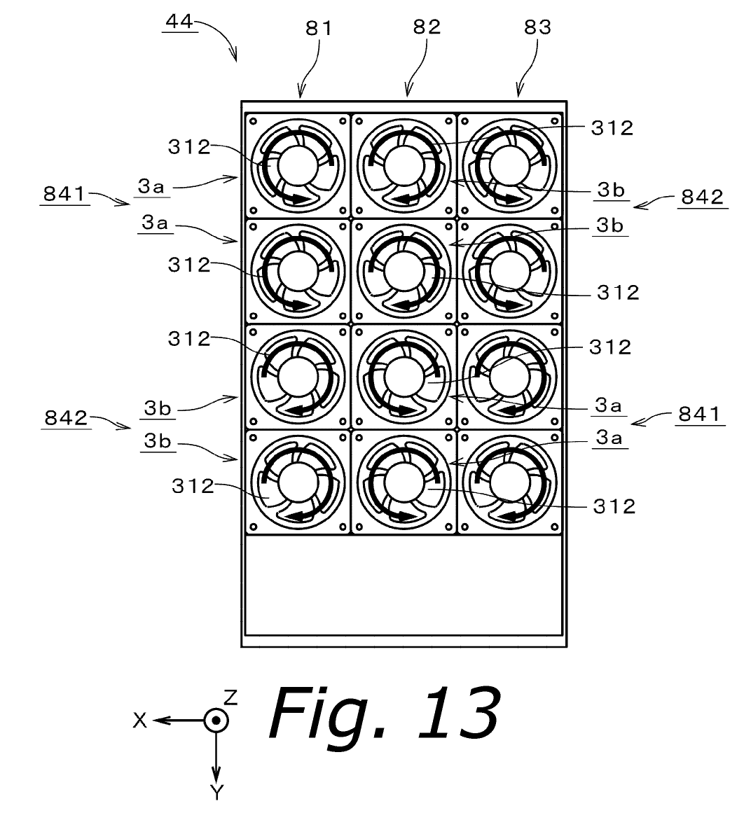

FIG. 13 is a plan view of an example modification of the fan apparatus 44. Similar to the fan apparatus 44 illustrated in FIG. 12, the fan apparatus 44 according to this example modification includes an array of axial fans 3 arranged in four rows and three columns. In the first column 81, two first axial fans 3a are arranged in an upper portion thereof as shown in FIG. 13, while two second axial fans 3b are arranged in a lower portion thereof. The same is true of the third column 83. In the second column 82, two second axial fans 3b are arranged in an upper portion thereof, while two first axial fans 3a are arranged in a lower portion thereof. In other words, each of the columns 81 to 83 includes a block 841 of two first axial fans 3a and a block 842 of two second axial fans 3b. Hereinafter, the block 841 will be referred to as a “first fan block 841”, and the block 842 will be referred to as a “second fan block 842”.

Regarding the fan apparatus 44, near a boundary between each pair of first and second fan blocks 841 and 842 which are adjacent to each other in either the X direction or the Y direction, the top portions of the blades 312 of the first and second axial fans 3a and 3b are arranged to move in the same direction. This contributes to reducing the noise caused by the flows of air.

Moreover, since the fan apparatus 44 includes the first and second fan blocks 841 and 842, it is possible to assemble each individual block of axial fans 3 beforehand easily. This facilitates assemblage of the entire fan apparatus 44.

As described above, in each of the fan apparatuses 44 illustrated in FIGS. 12 and 13, half the axial fans 3 are first axial fans 3a while the remaining half are second axial fans 3b, and in addition, the first axial fans 3a and the second axial fans 3b are distributed evenly across the whole array of the axial fans 3. This enables air to be introduced into the case 41 such that the air introduced will spread across a wide range inside the case 41, or enables air in a wide range inside the case 41 to be discharged out of the case 41, while achieving a reduction in noise. Note that, in other modifications of the fifth preferred embodiment, the number of first axial fans 3a and the number of second axial fans 3b may not necessarily be equal to each other, but may each be only nearly half the total number of axial fans 3. Preferably, the difference between the number of first axial fans 3a and the number of second axial fans 3b is equal to or smaller than a third of the total number of axial fans 3. Note that the wording “at least one axial fan arranged to rotate in a first rotation direction is half or nearly half a total number of the plurality of axial fans” as used herein means that the number of axial fans arranged to rotate in the first rotation direction and the number of axial fans arranged to rotate in a second rotation direction are equal or nearly equal to each other.

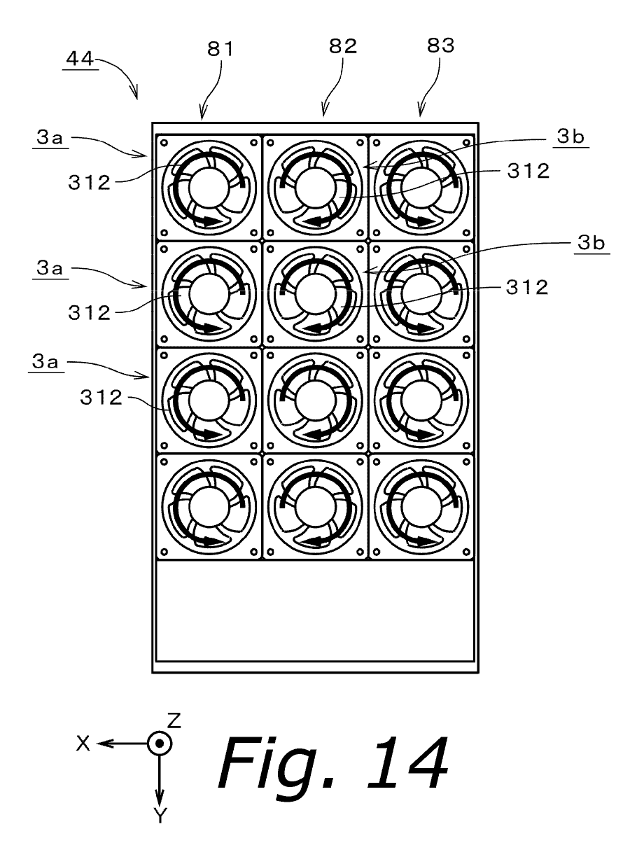

FIG. 14 is a plan view of still another example modification of the fan apparatus 44. In the fan apparatus 44 according to this example modification, a row of first axial fans 3a is arranged in the first column 81, a row of second axial fans 3b is arranged in the second column 82, and a row of first axial fans 3a is arranged in the third column 83. That is, the axial fans 3 in each column are arranged to rotate in an opposite direction to that in which the axial fans 3 in the adjacent column(s) are arranged to rotate. Thus, the top portions of the blades 312 of all the axial fans 3 in the first and second columns 81 and 82 are arranged to move in the same direction near a boundary between the first and second columns 81 and 82, while at the same time the top portions of the blades 312 of all the axial fans 3 in the second and third columns 82 and 83 are arranged to move in the same direction near a boundary between the second and third columns 82 and 83, so that a reduction in the noise caused by the flows of air is accomplished.

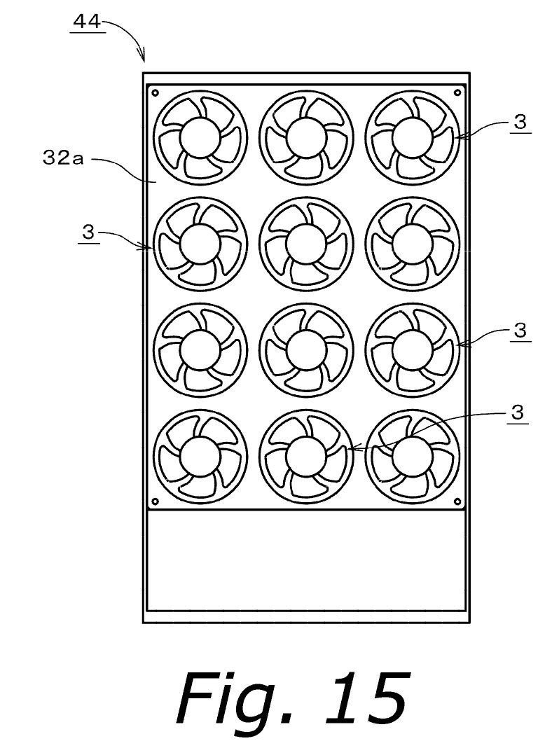

FIG. 15 is a plan view of still another example modification of the fan apparatus 44. The fan apparatus 44 according to this example modification is similar in structure to the fan apparatus 44 illustrated in FIG. 12 except that all the axial fans 3 share a common single-piece housing 32a. Use of the common single-piece housing 32a eliminates the need for an operation of joining the respective housings of the axial fans 3 together. Note that the technique of using a common single-piece housing 32a shared by a plurality of axial fans 3 may be adopted in modifications of any other preferred embodiment.

### Sixth Preferred Embodiment

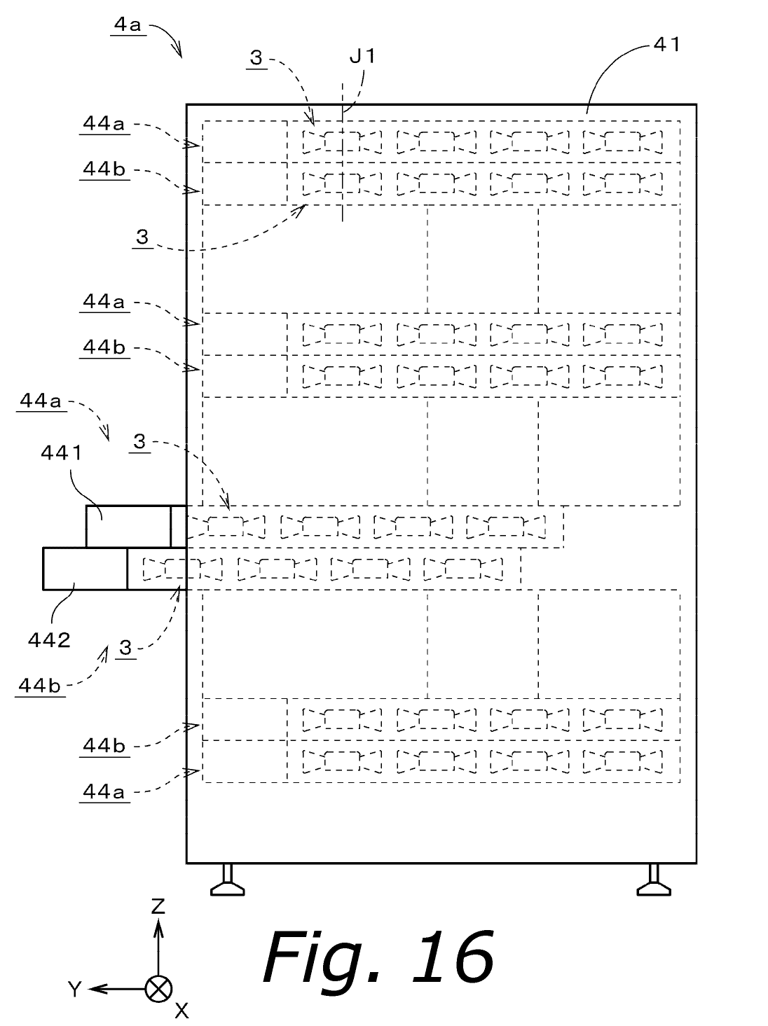

FIG. 16 is a right side view of a rack-type electronic system 4a according to a sixth preferred embodiment of the present invention, and corresponds to FIG. 11. The rack-type electronic system 4a is provided with a pair of first and second fan apparatuses 44a and 44b in place of each fan apparatus 44 in the rack-type electronic system 4 illustrated in FIG. 11. The first fan apparatus 44a is similar in structure to the fan apparatus 44 illustrated in FIG. 12.

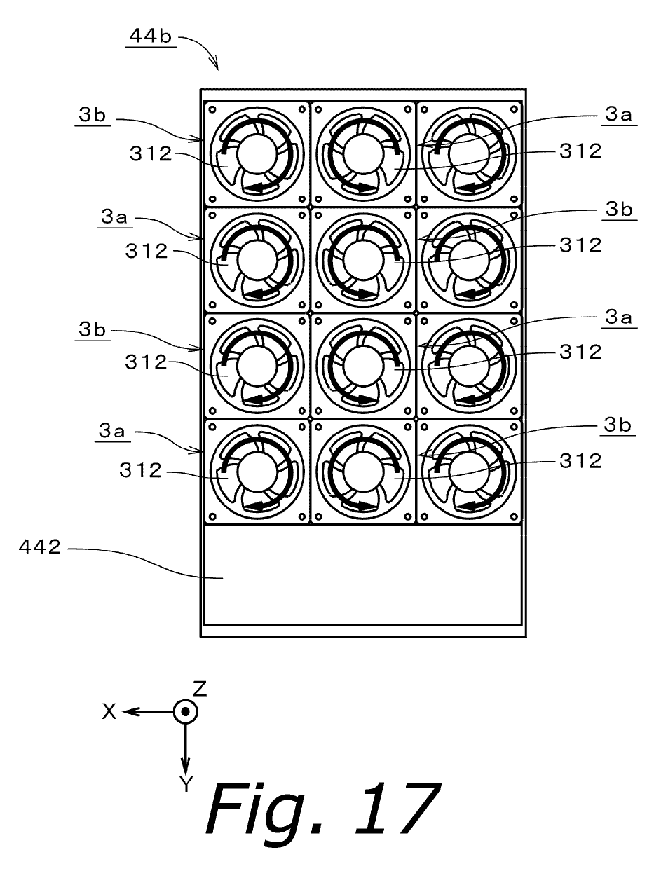

FIG. 17 is a plan view of the second fan apparatus 44b. The positions of the first and second axial fans 3a and 3b in the second fan apparatus 44b are reversed as compared to those in the fan apparatus 44 illustrated in FIG. 12. In the other respects, the rack-type electronic system 4a illustrated in FIG. 16 is similar in structure to the rack-type electronic system 4 illustrated in FIG. 11. The first and second fan apparatuses 44a and 44b in the rack-type electronic system 4a are driven to cause an upward flow of air.

As with the housings 32 of the axial fans 3 in the fan apparatus 44 illustrated in FIG. 12, the housings 32 of the axial fans 3 in the first fan apparatus 44a are joined together. In the case where the frame 441 is regarded as a horizontal mounting surface for the axial fans 3 provided in the case 41, the axial fans 3 are arranged in an array of four rows and three columns in parallel to the mounting surface. As illustrated in FIG. 16, the frame 441 is arranged to be capable of being horizontally inserted into and removed from the case 41 through the front of the case 41.

Also in the second fan apparatus 44b illustrated in FIG. 17, the housings 32 of the axial fans 3 are joined together. In the case where a frame 442 is regarded as a horizontal mounting surface for the axial fans 3 provided in the case 41, the axial fans 3 are arranged in an array of four rows and three columns in parallel to the mounting surface. In addition, as illustrated in FIG. 16, the frame 442 is arranged to be capable of being horizontally inserted into and removed from the case 41 through the front of the case 41.

The first and second fan apparatuses 44a and 44b in the rack-type electronic system 4a are placed one above the other in the Z direction. As a result, each of the first and second axial fans 3a and 3b in the second fan apparatus 44b illustrated in FIG. 17 is arranged in contact or close proximity with a separate one of the second and first axial fans 3b and 3a in the first fan apparatus 44a, which is similar to the fan apparatus 44 illustrated in FIG. 12, with the rotation axis J1 thereof coinciding with the rotation axis J1 of the separate one of the second and first axial fans 3b and 3a in the first fan apparatus 44a. That is, in the rack-type electronic system 4a illustrated in FIG. 16, each of the axial fans 3 in the second fan apparatus 44b and a separate one of the axial fans 3 in the first fan apparatus 44a which is arranged in contact or close proximity therewith along the rotation axes J1 are arranged to rotate in mutually opposite directions to each cause a flow of air in the same direction. This leads to an improvement in air static pressure-air volume characteristics.

This makes it possible to efficiently introduce, send, and discharge air into, inside, and out of the case 41, which contains the electronic components arranged densely. Note that the array of the axial fans 3 in the first fan apparatus 44a and the array of the axial fans 3 in the second fan apparatus 44b may be spaced from each other by a greater distance than in the case illustrated in FIG. 16, as long as a rotational velocity component of an air flow from each axial fan 3 on an inlet side serves to increase efficiency of the associated axial fan 3 on an outlet side in sending out the air.

Also in the sixth preferred embodiment, the top portions of the blades 312 of each pair of adjacent first and second axial fans 3a and 3b in the first fan apparatus 44a are arranged to move in the same direction near the boundary between the pair. This contributes to reducing the noise caused by the flows of air. The same is true of the second fan apparatus 44b. In modifications of the rack-type electronic system 4a, the array of the first and second axial fans 3a and 3b in the first fan apparatus 44a may be similar to that illustrated in FIG. 13 or 14. In such modifications, the positions of the first and second axial fans 3a and 3b in the second fan apparatus 44b are reversed as compared to those illustrated in FIG. 13 or 14.

### Seventh Preferred Embodiment

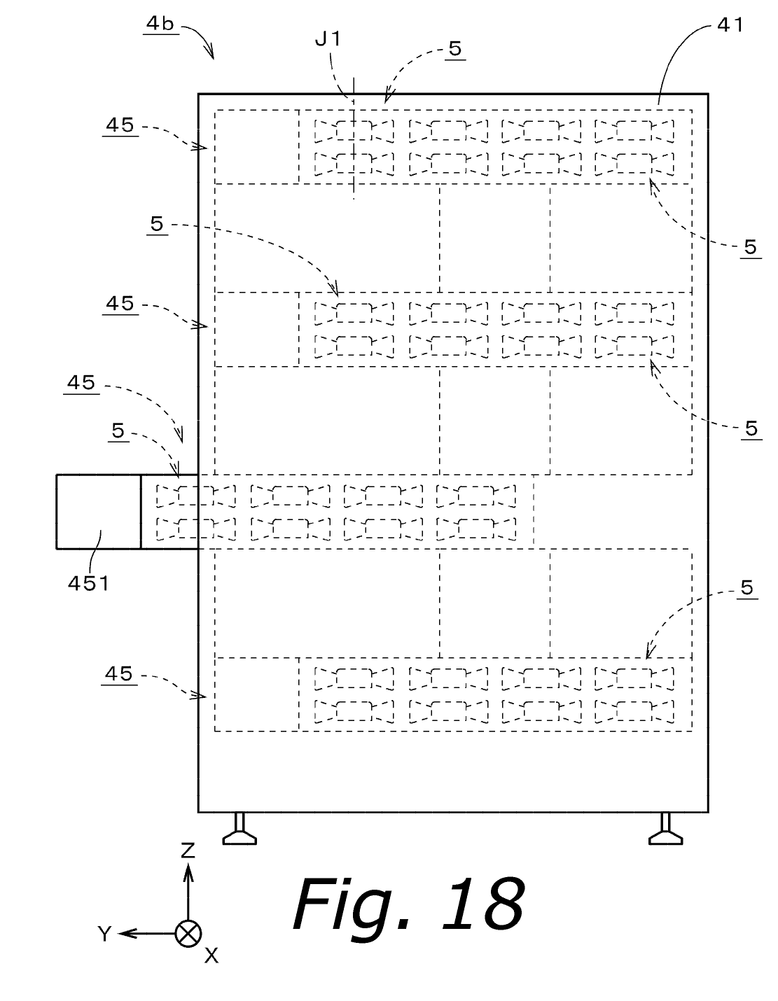

FIG. 18 is a right side view of a rack-type electronic system 4b according to a seventh preferred embodiment of the present invention. Fan apparatuses 45 in the rack-type electronic system 4b are each, in essence, a combination of the first and second fan apparatuses 44a and 44b as illustrated in FIG. 16 joined together, and each include a plurality of contra-rotating fans 5. The contra-rotating fans 5 are arranged in a horizontal two-dimensional array in the X and Y directions. Thus, the collection of the contra-rotating fans 5 corresponds to a combination of a two-dimensional array of a plurality of axial fans and another two-dimensional array of a plurality of axial fans which are arranged in contact or close proximity with each other in an axial direction.

In the other respects, the rack-type electronic system 4b is similar in structure to the rack-type electronic system 4a illustrated in FIG. 16. As with the axial fans 3 illustrated in FIG. 12, the contra-rotating fans 5 are arranged in an array of four rows and three columns, with rotation axes thereof extending perpendicularly or substantially perpendicularly to a frame 451 defining a horizontal mounting surface provided in the case 41. Each fan apparatus 45 in the rack-type electronic system 4b is arranged to be capable of being horizontally, i.e., in parallel or substantially in parallel to the frame 451, inserted into and removed from the case 41.

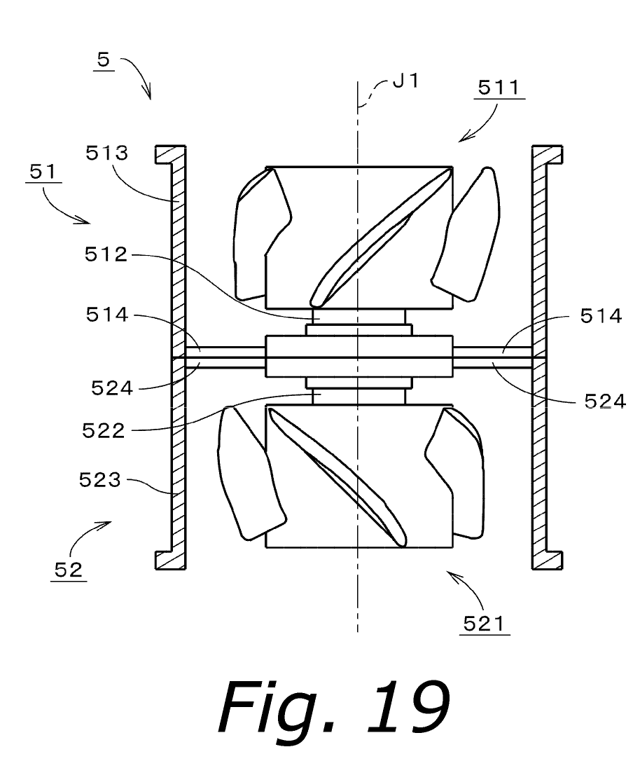

FIG. 19 is a partial cross-sectional view of one of the contra-rotating fans 5. Note, however, that the collection of the contra-rotating fans 5 include those contra-rotating fans 5 whose rotation directions are opposite to those of the contra-rotating fan 5 illustrated in FIG. 19. The contra-rotating fan 5 includes an upper fan portion 51 and a lower fan portion 52 arranged below the upper fan portion 51 and joined to the upper fan portion 51 along the rotation axis J1. The upper fan portion 51 includes an impeller 511, a motor 512, a housing 513, and a rib 514. The rib 514 is arranged to support the motor 512 in relation to the housing 513. The lower fan portion 52 includes an impeller 521, a motor 522, a housing 523, and a rib 524. The rib 524 is arranged to support the motor 522 of the lower fan portion 52 in relation to the housing 523. The relative vertical positions of the impeller and the motor are reversed between the upper and lower fan portions 51 and 52. That is, the impeller 521 is arranged below the motor 522 in the lower fan portion 52, while the impeller 511 is arranged above the motor 512 in the upper fan portion 51.

The housing 513 of the upper fan portion 51 is joined to the housing 523 of the lower fan portion 52 in a vertical direction. In FIG. 19, a mechanism to join the housings 513 and 523 to each other is omitted from illustration. In addition, the rib 514 of the upper fan portion 51 and the rib 524 of the lower fan portion 52 are arranged in contact with each other in the vertical direction. Note that the ribs 514 and 524 may be arranged only in close proximity with each other.

In the contra-rotating fan 5, the impeller 511 of the upper fan portion 51 and the impeller 521 of the lower fan portion 52 are arranged to rotate in mutually opposite directions, so that an improvement in the air static pressure-air volume characteristics is achieved. It is possible to manufacture each fan apparatus 45 in the rack-type electronic system 4b at a low cost, by using known contra-rotating fans.

In the rack-type electronic system 4b, the upper fan portions 51 in each pair of adjacent contra-rotating fans 5 are arranged to rotate in mutually opposite directions, while at the same time the lower fan portions 52 in each pair of adjacent contra-rotating fans 5 are arranged to rotate in mutually opposite directions. This contributes to reducing the noise caused by the flows of air. In modifications of the seventh preferred embodiment, the upper fan portions 51 in the array of the contra-rotating fans 5 may be respectively arranged to rotate in the directions in which the axial fans 3 in the fan apparatus 44 illustrated in FIG. 13 or the fan apparatus 44 illustrated in FIG. 14 are arranged to rotate. In such modifications, the lower fan portions 52 are respectively arranged to rotate in opposite directions to those in which the axial fans 3 illustrated in FIG. 13 or 14 are arranged to rotate.

While preferred embodiments of the present invention have been described above, it will be understood that the present invention is not limited to the above-described preferred embodiments, but that a variety of modifications are possible. In each of the first to sixth preferred embodiments described above, at least one of the axial fans 3 in the fan apparatus is preferably arranged to rotate in an opposite direction to that in which all the other axial fans 3 are arranged to rotate, to achieve a reduction in noise in the air introduction or discharge. In the seventh preferred embodiment, the upper and lower fan portions 51 and 52 in at least one of the contra-rotating fans 5 preferably are arranged to rotate in opposite directions to those in which the upper and lower fan portions 51 and 52, respectively, in each of the other contra-rotating fans 5 are arranged to rotate, to achieve a reduction in noise.

In each of the first and second preferred embodiments described above, the fan apparatus 23 is preferably attached to the rear surface of the case 21 of the electronic device 10. Note, however, that in modifications thereof, the fan apparatus 23 may be attached to any other principal surface of the case 21, such as a side surface of the case 21. Also note that in modifications thereof, the fan apparatus 23 may include three or more rows of axial fans 3. In such modifications thereof, the axial fans 3 in each row are preferably arranged to rotate in an opposite direction to that in which the axial fans 3 in the adjacent row(s) are arranged to rotate. Alternatively, each pair of axial fans 3 which are adjacent to each other in either the row direction or the column direction of the array may preferably be arranged to rotate in mutually opposite directions. In modifications of each of the first and second preferred embodiments, any number of axial fans 3 may be used in the fan apparatus 23, as long as the axial fans 3 are arranged in an array of at least two rows and at least two columns. The same is true of both the third and fourth preferred embodiments.

In modifications of each of the fifth to seventh preferred embodiments described above, any number of fans may be used in the fan apparatus 44, 44a, 44b, or 45, as long as the fans, i.e., the axial fans 3 or the contra-rotating fans 5, are arranged in an array of at least two rows and at least two columns.

In modifications of the fan apparatus 44 illustrated in FIG. 13, four or more columns of axial fans 3 may be arranged. In such modifications, a collection of axial fans 3 arranged in an array of two or more rows and two or more columns and arranged to rotate in the same direction may be regarded as a fan block. Various modifications of the structure and arrangement of the first and second fan blocks are possible, as long as each of a plurality of first fan blocks is a collection of adjacent axial fans arranged to rotate in the same direction, each of a plurality of second fan blocks is a collection of adjacent axial fans arranged to rotate in an opposite direction to that in which the axial fans in the first fan blocks are arranged to rotate, and each first fan block is arranged adjacent to one or more of the second fan blocks.

In modifications of each of the first to fourth preferred embodiments described above, more than one fan apparatus may be attached to the same mounting surface. In modifications of each of the fifth to seventh preferred embodiments described above, a fan apparatus similar to the fan apparatus according to any of the first to fourth preferred embodiments, or a fan apparatus similar to the fan apparatus according to any of the fifth to seventh preferred embodiments, may be attached to a side surface, a rear surface, or the like of the case 41.

In modifications of the fourth preferred embodiment, the structure of the third fan apparatus 23c is not limited to the 2×2 array, as long as an imaginary plane which is parallel or substantially parallel to the X-Y plane and includes the boundary 931 in the first fan apparatus 23a illustrated in FIG. 9 and the boundary 932 in the second fan apparatus 23b is arranged to intersect with the third fan apparatus 23c. For example, only two axial fans 3 arranged to rotate in mutually opposite directions may be arranged in the third fan apparatus 23c.

In modifications of the contra-rotating fan 5 illustrated in FIG. 19, the housing 513 of the upper fan portion and the housing 523 of the lower fan portion 52 may be replaced with a single-piece housing shared by the upper and lower fan portions 51 and 52. Moreover, in modifications of the fan apparatus 45 according to the seventh preferred embodiment, the housings 513 and 523 of all the contra-rotating fans 5 arranged in the fan apparatus 45 may be replaced with a single-piece housing shared by all the contra-rotating fans 5. In modifications of each of the fifth to seventh preferred embodiments described above, the joining of the housings in directions perpendicular or substantially perpendicular to the rotation axes J1 may be accomplished, instead of through the frame, directly through the housings themselves by using a joining member or the like. Also in such modifications thereof, the collection of the axial fans 3 or of the contra-rotating fans 5 are arranged to be capable of being inserted into and removed from the case 41 in a direction parallel or substantially in parallel to the predetermined mounting surface provided in the case 41. An electronic device according to a preferred embodiment of the present invention may be either an electronic device as a single complete product, or a component of an electronic device system, such as a power supply or a light source. Examples of such single complete products include, for example, a computer, a server system, a large router, and a home appliance product, such as audio-visual (AV) equipment.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A fan apparatus comprising:
an array of a plurality of axial fans arranged in at least two rows and at least two columns in parallel or substantially in parallel with a mounting surface provided in a case of an electronic device, each of the plurality of axial fans including a rotation axis extending perpendicularly or substantially perpendicularly to the mounting surface; wherein
at least one of the plurality of axial fans is arranged to rotate in a first rotation direction to introduce air into the case or discharge air out of the case, and at least one other of the plurality of axial fans is arranged to rotate in a second rotation direction opposite to the first rotation direction to cause a flow of air in a same direction in which the at least one of the plurality of axial fans is arranged to cause a flow of air.

2. The fan apparatus according to claim 1, wherein the at least one of the plurality of axial fans is half or nearly half of a total number of the plurality of axial fans, and is distributed evenly across the whole array of the plurality of axial fans.

3. The fan apparatus according to claim 2, wherein, in both row and column directions of the array, each of the plurality of axial fans is arranged adjacent to one or two of the plurality of axial fans which are arranged to rotate in an opposite direction.

4. The fan apparatus according to claim 2, wherein
the plurality of axial fans include a plurality of first fan blocks and a plurality of second fan blocks;
each of the plurality of first fan blocks includes at least two of the plurality of axial fans which are arranged adjacent to one another and arranged to rotate in the first rotation direction, and each of the second fan blocks includes at least two of the plurality of axial fans which are arranged adjacent to one another and arranged to rotate in the second rotation direction; and
each of the plurality of first fan blocks is arranged adjacent to one or more of the plurality of second fan blocks.

5. A fan-attached case comprising:
the fan apparatus of claim 3; and
a case having the fan apparatus attached thereto; wherein
the fan apparatus includes four axial fans arranged in an array of two rows and two columns;
the fan apparatus is arranged substantially in a middle in a longitudinal direction of a principal surface of the case; and
the fan apparatus is arranged to discharge air out of the case, and two of four boundaries between the four axial fans near which blades of all the four axial fans are arranged to move in a direction of a center of the array of the four axial fans are oriented parallel or substantially parallel to the longitudinal direction; or
the fan apparatus is arranged to introduce air into the case, and two of the four boundaries near which the blades of all the four axial fans are arranged to move in a direction away from the center of the array are oriented parallel or substantially parallel to the longitudinal direction.

6. An electronic device comprising:
the fan-attached case of claim 5; and
a circuit board arranged inside the case perpendicularly or substantially perpendicularly to the principal surface; wherein
the circuit board is arranged along the two of the four boundaries which are oriented parallel or substantially parallel to the longitudinal direction.

7. The fan apparatus according to claim 1, wherein the plurality of axial fans include:
a plurality of first axial fans arranged in a row parallel or substantially parallel to the mounting surface, and arranged to rotate in the first rotation direction; and
a plurality of second axial fans arranged in a row parallel or substantially parallel to the mounting surface and the row of the plurality of first axial fans, and arranged to rotate in the second rotation direction.

8. The fan apparatus according to claim 7, wherein
in the array of the plurality of axial fans, the plurality of axial fans are arranged in three or more rows parallel or substantially parallel to the row of the plurality of first axial fans; and
the axial fans in each row are arranged to rotate in an opposite direction from that in which the axial fans in an adjacent row or rows are arranged to rotate.

9. The fan apparatus according to claim 7, wherein the plurality of axial fans include the single row of the plurality of first axial fans and the single row of the plurality of second axial fans.

10. A fan-attached case comprising:
the fan apparatus of claim 9; and
a case having the fan apparatus attached thereto; wherein
the fan apparatus is arranged one-sidedly near a side of the case;
a boundary between the row of the plurality of first axial fans and the row of the plurality of second axial fans is perpendicular to the side; and
the fan apparatus is arranged to discharge air out of the case, and blades of all of the plurality of first axial fans and the plurality of second axial fans are arranged to move in a direction of the side near the boundary; or
the fan apparatus is arranged to introduce air into the case, and the blades of all of the plurality of first axial fans and the plurality of second axial fans are arranged to move in a direction away from the side near the boundary.

11. An electronic device comprising:
the fan-attached case of claim 10; and
a circuit board arranged inside the case perpendicularly or substantially perpendicularly to the side and along the boundary.

12. The fan apparatus according to claim 1, wherein the array of the plurality of axial fans is arranged to be capable of being inserted into and removed from the case in a direction parallel or substantially parallel to the mounting surface.

13. The fan apparatus according to claim 1, wherein the plurality of axial fans either share a common single-piece housing or have separate housings joined together.

14. A fan-attached case comprising:
a case;
a first fan apparatus corresponding to the fan apparatus of claim 9, the first fan apparatus being attached to a first principal surface of the case; and
a second fan apparatus corresponding to the fan apparatus of claim 9, the second fan apparatus being attached to a second principal surface of the case, the second principal surface being arranged opposite the first principal surface; wherein
the first and second fan apparatuses are arranged symmetrically with respect to an imaginary plane parallel or substantially parallel to both the first and second principal surfaces, and positioned in a middle between the first and second principal surfaces.

15. The fan-attached case according to claim 14, further comprising a third fan apparatus attached to a third principal surface of the case, the third principal surface extending between the first and second principal surfaces; wherein
an imaginary plane including both a boundary between the row of the plurality of first axial fans and the row of the plurality of second axial fans in the first fan apparatus, and a boundary between the row of the plurality of first axial fans and the row of the plurality of second axial fans in the second fan apparatus is arranged to intersect with the third fan apparatus; and
each of the first and second fan apparatuses is arranged to discharge air out of the case, blades of all the first and second axial fans in each of the first and second fan apparatuses are arranged to move in a direction away from the third fan apparatus near the boundary, and the third fan apparatus is arranged to introduce the air into the case; or
each of the first and second fan apparatuses is arranged to introduce air into the case, the blades of all the first and second axial fans in each of the first and second fan apparatuses are arranged to move in a direction of the third fan apparatus near the boundary, and the third fan apparatus is arranged to discharge the air out of the case.

16. The fan apparatus according to claim 4, wherein the array is a first array, the fan apparatus further comprising a second array of a plurality of axial fans arranged in parallel or substantially parallel with the mounting surface, each of the axial fans in the second array having a rotation axis coinciding with the rotation axis of a separate one of the plurality of axial fans in the first array, and being arranged in contact or close proximity with the separate one of the plurality of axial fans in the first array along the rotation axes, wherein each of the plurality of axial fans in the second array and the separate one of the plurality of axial fans in the first array are arranged to rotate in mutually opposite directions to each cause a flow of air in a same direction.

17. The fan apparatus according to claim 16, wherein
the plurality of axial fans in the first array either share a common single-piece housing or have separate housings joined together, and the plurality of axial fans in the second array also either share a common single-piece housing or have separate housings joined together; and
the first array of the plurality of axial fans is arranged to be capable of being inserted into and removed from the case in a direction parallel or substantially parallel to the mounting surface, and the second array of the plurality of axial fans is also arranged to be capable of being inserted into and removed from the case in the same direction parallel or substantially parallel to the mounting surface.

18. The fan apparatus according to claim 16, wherein
each of the plurality of axial fans in the second array and the separate one of the plurality of axial fans in the first array, arranged in contact or close proximity with each other along the rotation axes, either share a common single-piece housing or have separate housings joined together; and
a unified collection of the first array of the plurality of axial fans and the second array of the plurality of axial fans is arranged to be capable of being inserted into and removed from the case in a direction parallel or substantially parallel to the mounting surface.
